(19) United States
(12) Patent Application Publication
(10) Pub. No.: US 2024/0388275 A1
(43) Pub. Date: Nov. 21, 2024

(54) ACOUSTIC WAVE DEVICE

(71) Applicant: Murata Manufacturing Co., Ltd., Nagaokakyo-shi (JP)

(72) Inventors: Toru YAMAJI, Nagaokakyo-shi (JP); Takuma KUZUSHITA, Nagaokakyo-shi (JP); Masato KYOYA, Nagaokakyo-shi (JP)

(21) Appl. No.: 18/786,653

(22) Filed: Jul. 29, 2024

Related U.S. Application Data
(63) Continuation of application No. PCT/JP2023/003048, filed on Jan. 31, 2023.

(30) Foreign Application Priority Data
Feb. 9, 2022 (JP) 2022-018612

(51) Int. Cl. H03H 9/05; H03H 9/10; H03H 9/145

(52) U.S. Cl. CPC H03H 9/059; H03H 9/1085; H03H 9/145

(57) ABSTRACT

An acoustic wave device includes a piezoelectric substrate including a functional electrode on a first main surface of the piezoelectric substrate, a functional wire on the first main surface and connected to the functional electrode, and a connection wire on the first main surface, connected to the functional wire, and extending to an edge portion of the first main surface. An acoustic wave element chip is defined by the piezoelectric substrate, the functional electrode, the functional wire, and the connection wire. The acoustic wave device includes a mounting substrate on which the acoustic wave element chip is mounted and including a third main surface facing the first main surface of the piezoelectric substrate, and a mounting substrate wire on the third main surface. D1<(D2²+H1²)^{0.5} is satisfied.

### CROSS REFERENCE TO RELATED APPLICATIONS

This application claims the benefit of priority to Japanese Patent Application No. 2022-018612 filed on Feb. 9, 2022 and is a Continuation Application of PCT Application No. PCT/JP2023/003048 filed on Jan. 31, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have been widely used for filters of cellular phones and the like. Japanese Unexamined Patent Application Publication No. 2002-319841 discloses an example of a surface acoustic wave device having a plurality of IDT (interdigital transducer) electrodes. The surface acoustic wave device is obtained by dividing a wafer piezoelectric substrate, in which a plurality of surface acoustic wave device precursors are formed, by dicing.

The surface acoustic wave device precursor has a routing electrode and a plurality of probe electrode pads. After performing inspection using the probe electrode pads, the piezoelectric substrate is divided.

In the surface acoustic wave device described in Japanese Unexamined Patent Application Publication No. 2002-319841, the probe electrode pads are cut by a dicing blade during dicing. At this time, there is a risk that a routing wire may peel off due to a metal film defining the probe electrode pads being dragged in. Further, there is a risk that the routing wire may peel off due to microcracks in the piezoelectric substrate generated when the piezoelectric substrate is being divided.

The surface acoustic wave device is flip-chip mounted on a mounting substrate, for example. However, when the routing wire peels off, the routing wire may come into contact with wires on the mounting substrate. In such a case, the electrical characteristics of the surface acoustic wave device will be degraded.

### SUMMARY OF THE INVENTION

Example embodiments of the present invention provide acoustic wave devices each able to reduce or prevent contact between wires on a mounting substrate and wires on a piezoelectric substrate and able to reduce or prevent degradation of electrical characteristics.

An acoustic wave device according to an example embodiment of the present invention includes a piezoelectric substrate including a first main surface and a second main surface facing each other, a functional electrode on the first main surface of the piezoelectric substrate, a functional wire on the first main surface of the piezoelectric substrate and connected to the functional electrode, and a connection wire on the first main surface of the piezoelectric substrate, connected to the functional wire, and extending to an edge portion of the first main surface. An acoustic wave element chip includes the piezoelectric substrate, the functional electrode, the functional wire, and the connection wire. The acoustic wave device further includes a mounting substrate on which the acoustic wave element chip is mounted and including a third main surface facing the first main surface of the piezoelectric substrate, and a mounting substrate wire on the third main surface of the mounting substrate and including a first surface on an acoustic wave element chip side and a second surface facing the first surface. D1<(D2²+H1²)^{0.5} is satisfied, when a portion where the functional wire and the connection wire are connected is a connection portion, a portion of the mounting substrate overlapping the connection portion in plan view is a reference portion, a length of the connection wire is D1, a minimum distance between the reference portion and the mounting substrate wire is D2, and a distance between the first main surface of the piezoelectric substrate and the first surface of the mounting substrate wire is H1.

Acoustic wave devices according to example embodiments of the present invention are each able to reduce or prevent contact between wires on a mounting substrate and wires on a piezoelectric substrate and reduce or prevent degradation of electrical characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic front sectional view of an acoustic wave device according to a first example embodiment of the present invention.

FIG. 2 is a schematic transparent plan view of an acoustic wave element chip according to the first example embodiment of the present invention.

FIG. 3 is a schematic plan view of a mounting substrate according to the first example embodiment of the present invention.

FIG. 4 is a schematic front sectional view showing an enlarged area near a connection wire of the first example embodiment of the present invention.

FIG. 5 is a schematic plan view showing a portion of a substrate to be divided when obtaining the acoustic wave element chip of the first example embodiment of the present invention.

FIG. 6 is a schematic bottom view showing the electrode structure of an acoustic wave resonator of the first example embodiment of the present invention.

FIG. 7 is a schematic bottom view showing an enlarged area near the connection wire and a functional wire of the first example embodiment of the present invention.

FIG. 8 is a schematic sectional view showing an area near a connection wire and a functional wire of a first variation of the first example embodiment of the present invention, sectioned along a direction in which the connection wire extends.

FIG. 9 is a schematic bottom view showing the area near the connection wire and the functional wire of the first variation of the first example embodiment of the present invention.

FIG. 10 is a schematic bottom view showing an area near a connection wire and a functional wire of a second variation of the first example embodiment of the present invention.

FIG. 11 is a schematic bottom view showing an area near a connection wire and a functional wire of a third variation of the first example embodiment of the present invention.

FIG. 12 is a schematic front sectional view of an acoustic wave device according to a fourth variation of the first example embodiment of the present invention.

FIG. 13 is a schematic bottom view of an acoustic wave element chip according to a second example embodiment of the present invention.

FIG. 14 is a schematic plan view showing a portion of a substrate to be divided when obtaining the acoustic wave element chip of the second example embodiment of the present invention.

FIG. 15 is a schematic bottom view of an acoustic wave element chip according to a third example embodiment of the present invention.

FIG. 16 is a schematic plan view showing a portion of a substrate to be divided when obtaining the acoustic wave element chip of the third example embodiment of the present invention.

FIGS. 17A to 17C are views showing examples of alignment marks.

FIG. 18 is a schematic bottom view of an acoustic wave element chip according to a fourth example embodiment of the present invention.

FIG. 19 is a schematic plan view showing a portion of a substrate to be divided when obtaining the acoustic wave element chip of the fourth example embodiment of the present invention.

FIG. 20 is a schematic bottom view showing an enlarged part of an acoustic wave element chip according to a fifth example embodiment of the present invention.

FIG. 21 is a schematic plan view showing a portion of a substrate to be divided when obtaining the acoustic wave element chip of the fifth example embodiment of the present invention.

### DETAILED DESCRIPTION OF THE EXAMPLE EMBODIMENTS

The present invention will be clarified below by describing specific example embodiments of the present invention with reference to the drawings.

Each of the example embodiments described in the present description is exemplary, and partial substitution or combination of configurations is possible between different example embodiments.

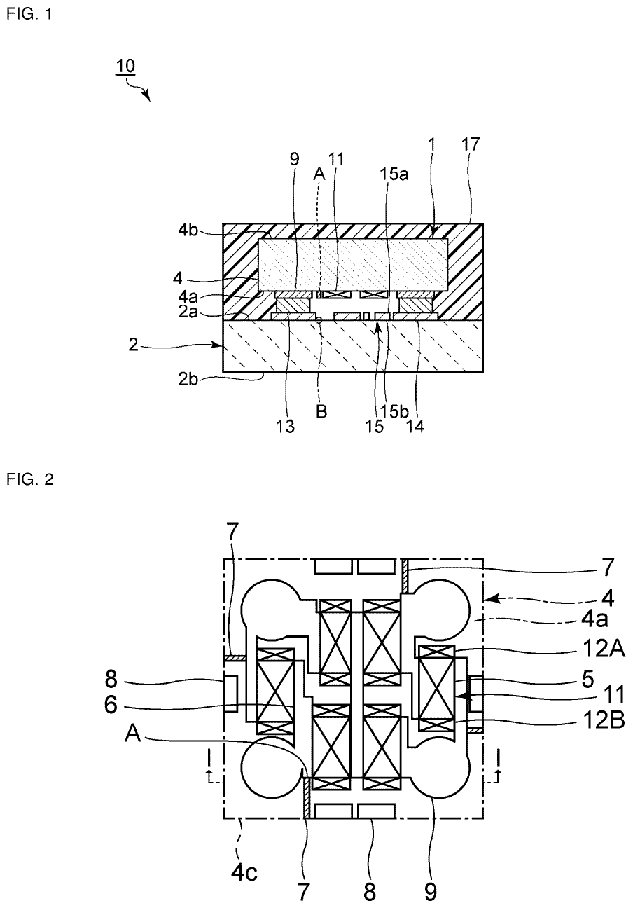

FIG. 1 is a schematic front sectional view of an acoustic wave device according to a first example embodiment of the present invention. In FIG. 1, acoustic wave resonators, which will be described later, are each shown by a schematic diagram obtained by adding two diagonals to a rectangle. The same goes for the schematic plan views and the like that follow.

An acoustic wave device 10 includes an acoustic wave element chip 1 and a mounting substrate 2. The acoustic wave element chip 1 includes a piezoelectric substrate 4. In the present example embodiment, the piezoelectric substrate 4 is, for example, a substrate made only of a piezoelectric material. The piezoelectric substrate 4 includes a first main surface 4a and a second main surface 4b. The first main surface 4a and the second main surface 4b face each other. A plurality of acoustic wave resonators 11 are provided on the first main surface 4a. On the other hand, the mounting substrate 2 includes a third main surface 2a and a fourth main surface 2b. The third main surface 2a and the fourth main surface 2b face each other. The acoustic wave element chip 1 is flip-chip mounted on the third main surface 2a of the mounting substrate 2. Therefore, the third main surface 2a of the mounting substrate 2 faces the first main surface 4a of the piezoelectric substrate 4. A sealing resin layer 17 is provided on the third main surface 2a of the mounting substrate 2 to cover the acoustic wave element chip 1.

A piezoelectric material such as, for example, lithium tantalate, lithium niobate, zinc oxide, aluminum nitride, quartz, or PZT (lead zirconate titanate) can be used as the material of the piezoelectric substrate 4. For example, a glass epoxy resin or a suitable ceramic can be used as the material of the mounting substrate 2.

Hereinafter, as the direction in FIG. 1, among the first main surface 4a and the second main surface 4b of the piezoelectric substrate 4, the second main surface 4b side is defined as an upper side and the first main surface 4a side is defined as a lower side. Viewing the acoustic wave device 10 from the upper side to the lower side in FIG. 1 is defined as plan view, and viewing the acoustic wave device 10 from the lower side to the upper side is defined as bottom view.

FIG. 2 is a schematic transparent plan view of the acoustic wave element chip according to the first example embodiment. In FIG. 2, connection wires to be described later are indicated by hatching. The same goes for the other schematic plan views, schematic bottom views, and schematic sectional views. FIG. 1 is a schematic sectional view taken along I-I line of FIG. 2.

The first main surface 4a of the piezoelectric substrate 4 includes an edge portion 4c. More specifically, in the present example embodiment, the shape of the first main surface 4a is rectangular or substantially rectangular. Therefore, the edge portion 4c includes portions corresponding to the four sides.

A plurality of functional electrodes, a plurality of functional wires 6, a plurality of connection wires 7, a plurality of electrode pads 8, and a plurality of bump pads 9 are provided on the first main surface 4a of the piezoelectric substrate 4. In the present example embodiment, each of the functional electrodes is, for example, an IDT electrode 5. The functional wire 6 is a wire that connects functional elements with each other or connects the functional element with the bump pad 9 on the piezoelectric substrate 4. The functional element is, for example, an inductive element such as an inductor, a capacitive element, or a resonator. In the present example embodiment, the IDT electrodes 5, as the functional electrodes, are provided on the piezoelectric substrate 4 to define the acoustic wave resonator 11. Each of the functional wires 6 is connected to one of the IDT electrodes 5. Some of the plurality of functional wires 6 connect the IDT electrodes 5 to each other. Others of the plurality of functional wires 6 connect the bump pads 9 and at least one IDT electrode 5.

The connection wire 7 includes one end portion connected to the functional wire 6 and the other end portion reaching the edge portion 4c of the piezoelectric substrate 4. Specifically, as shown in FIG. 2, each of the plurality of connection wires 7 is connected to one of the functional wires 6. The portion where the connection wire 7 and the functional wire 6 are connected is a connection portion A. The plurality of connection wires 7 each extend from the connection portion A toward the edge portion 4c of the first main surface 4a of the piezoelectric substrate 4. Each of the connection wires 7 extends to the edge portion 4c. In the present example embodiment, the connection portion A is one end portion of the connection wire 7. The other end portion of the connection wire 7 extends to the edge portion 4c. The portion where the connection wire 7 and the functional wire 6 are connected may extend in the direction in which the connection wire 7 extends. In such a case, it is assumed that the connection portion A is a portion, of the portion where the connection wire 7 and the functional wire 6 are connected, that is closest to the edge portion 4c where the connection wire 7 reaches.

Each of the plurality of electrode pads 8 extends to the edge portion 4c. The plurality of electrode pads 8 are floating electrodes. In the present description, the floating electrode refers to an electrode that is not connected to the signal potential or the ground potential. However, the plurality of electrode pads 8 need not be floating electrodes.

The plurality of electrode pads 8 are used to inspect electrical characteristics during the manufacture of the acoustic wave device 10. During the inspection, the plurality of electrode pads 8 are electrically connected to the IDT electrodes 5. More specifically, the acoustic wave element chip 1 is obtained by dicing a substrate on which a plurality of elements are provided. Before dicing, each of the electrode pads 8 is electrically connected to one of the IDT electrodes 5 by the connection wire 7. By cutting the respective connection wires 7 by dicing, the electrode pads 8 become the floating electrodes.

The inspection is used, for example, to select non-defective products. By proceeding with the process only for the non-defective products, productivity can be improved.

The thickness of the connection wire 7 is smaller than the thickness of the functional wire 6. Thus, dicing can be easily performed.

As shown in FIG. 1, each of the bump pads 9 includes a bump 13. The bump 13 joins the first main surface 4a of the piezoelectric substrate 4 and the third main surface 2a of the mounting substrate 2. Each of the IDT electrodes 5 is electrically connected to the mounting substrate 2 via the functional wire 6, the bump pad 9 and the bump 13.

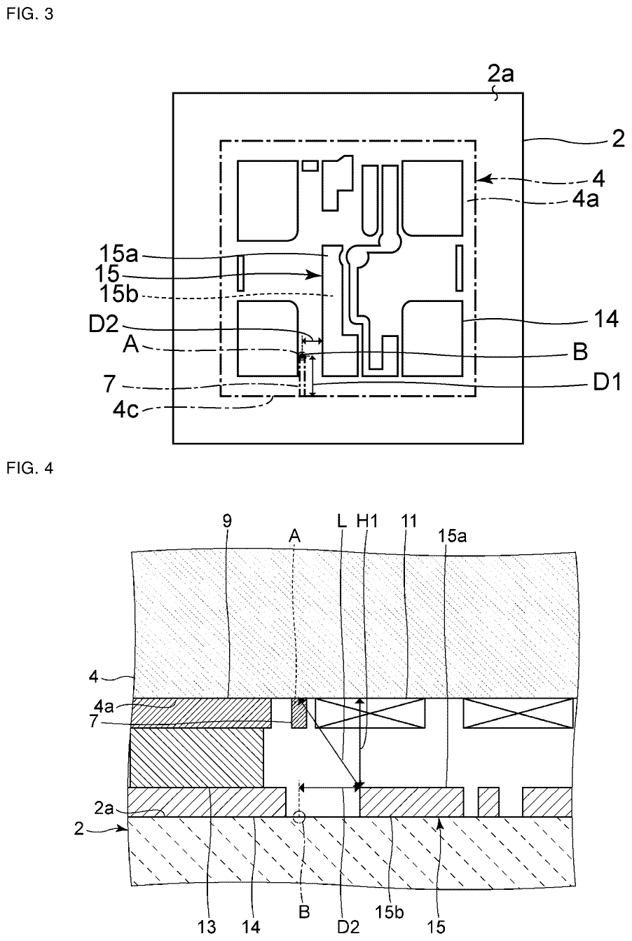

FIG. 3 is a schematic plan view of the mounting substrate according to the first example embodiment. FIG. 4 is a schematic front sectional view showing an enlarged area near the connection wire of the first example embodiment.

As shown in FIG. 3, a plurality of connection pads 14 and a plurality of mounting substrate wires 15 are provided on the third main surface 2a of the mounting substrate 2. Each of the connection pads 14 includes the bump 13 bonded to thereto. The mounting substrate wire 15 includes a first surface 15a and a second surface 15b. The first surface 15a and the second surface 15b face each other. Among the first surface 15a and the second surface 15b, the first surface 15a is on the acoustic wave element chip 1 side.

In FIG. 3, the connection wire 7 and the piezoelectric substrate 4 in the acoustic wave element chip 1 are indicated by single dotted lines. One end portion of the connection wire 7 is the connection portion A. A portion of the mounting substrate 2 that overlaps the connection portion A in plan view is a reference portion B. Hereinafter, the length of the connection wire 7 is referred to as D1. The minimum distance between the reference portion B and the mounting substrate wire 15 is referred to as D2. Further, as shown in FIG. 4, the distance between the first main surface 4a of the piezoelectric substrate 4 and the first surface 15a of the mounting substrate wire 15 is referred to as H1. In such a case, for example, L=(D2²+H1²)^{0.5}, where L is the minimum distance between the connection portion A and the mounting substrate wire 15.

A feature of the present example embodiment is that D1<L is satisfied. In other words, D1<(D2²+H1²)^{0.5} is satisfied in the present example embodiment. It is sufficient if D1<(D2²+H1²)^{0.5} is satisfied for at least one of the connection wires 7. Thus, the contact between the mounting substrate wire 15 and the connection wire 7 on the piezoelectric substrate 4 can be reduced or prevented, and the degradation of the electrical characteristics of the acoustic wave device 10 can be reduced or prevented. The details will be described below.

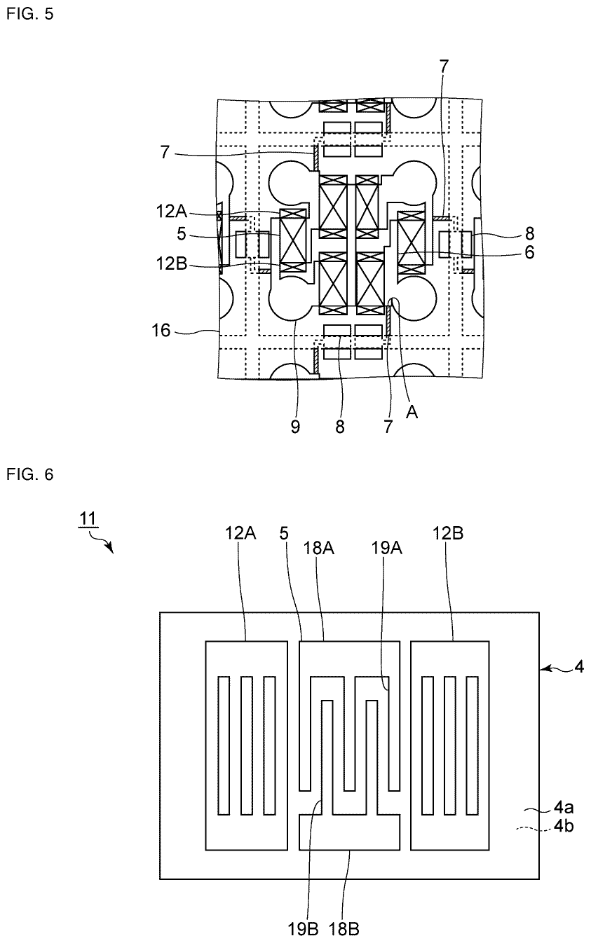

FIG. 5 is a schematic plan view showing a portion of a substrate to be divided when obtaining the acoustic wave element chip of the first example embodiment. Since FIG. 5 is a plan view of a state before the acoustic wave element chip 1 is flip-chip mounted, the shape of the wire arrangement and the like is inverted from that in FIG. 2.

As described above, the acoustic wave element chip 1 is obtained by dicing a substrate 16 on which a plurality of acoustic wave elements are provided. During dicing, a portion of the electrode pad 8 and a portion of the connection wire 7 are removed. In FIG. 5, the dicing line and the portions to be removed by dicing are indicated by dashed lines.

During dicing, the stress caused by the dicing blade dragging a portion of the connection wire 7 propagates to the IDT electrode 5 side. Thus, the connection wire 7 may peel off toward the IDT electrode 5 side. The connection wire 7 is connected to the functional wire 6 at the connection portion A. The thickness of the connection wire 7 is smaller than the thickness of the functional wire 6. Therefore, the connection wire 7 tends to peel off starting from the connection portion A.

When the connection wire 7 peels off, the connection wire 7 does not necessarily bend so that it overlaps the direction in which the connection wire 7 extends in plan view. In other words, the connection wire 7 may bend in a direction that does not overlap the direction in which the connection wire 7 extends in plan view.

If the connection wire peels off while the acoustic wave element chip is mounted on the mounting substrate, the connection wire may come into contact with the mounting substrate wire. In such a case, the electrical characteristics of the acoustic wave device will be degraded.

In contrast, in the present example embodiment, for example, D1<(D2²+H1²)^{0.5}=L is satisfied. Thus, the length D1 of the connection wire 7 is less than or equal to the minimum distance L between the connection portion A and the mounting substrate wire 15. Thus, even when the connection wire 7 peels off, it is difficult for the connection wire 7 to contact the mounting substrate wire 15. Therefore, the degradation of the electrical characteristics of the acoustic wave device 10 can be reduced or prevented. Alternatively, for example, D1≤(D2²+H1²)^{0.5} may be satisfied. Even in such a case, the contact between the connection wire 7 and the mounting substrate wire 15 can be reduced or prevented. However, it is preferable that D1<(D2²+H1²)^{0.5} is satisfied, as in the present example embodiment. Thus, the contact between the mounting substrate wire 15 and the connection wire 7 can be more reliably reduced or prevented.

Details of the acoustic wave resonator in the present example embodiment will be described below.

FIG. 6 is a schematic bottom view showing the electrode structure of the acoustic wave resonator of the first example embodiment. In FIG. 6, the wires connected to the acoustic wave resonator are omitted.

As described above, the functional electrode in the present example embodiment is, for example, the IDT electrode 5. By applying an AC voltage to the IDT electrode 5, an acoustic wave is excited. A pair of reflectors 12 A and 12B are provided on respective sides of the first main surface 4a of the piezoelectric substrate 4 in the acoustic wave propagation direction of the IDT electrode 5. Therefore, the acoustic wave resonator 11 in the present example embodiment is a surface acoustic wave resonator.

The IDT electrode 5 includes a first busbar 18A and a second busbar 18B, a plurality of first electrode fingers 19A and a plurality of second electrode fingers 19B. The first busbar 18A and the second busbar 18B face each other. One end of each of the plurality of first electrode fingers 19A is connected to the first busbar 18A. One end of each of the plurality of second electrode fingers 19B are connected to the second busbar 18B. The plurality of first electrode fingers 19A and the plurality of second electrode fingers 19B are interdigitated with each other. In the present example embodiment, the direction in which the plurality of first electrode fingers 19A and the plurality of second electrode fingers 19B extend is orthogonal or substantially orthogonal to the acoustic wave propagation direction. The IDT electrode 5, the reflector 12A, and the reflector 12B may include a multilayer metal film or a single layer metal film.

A preferred configuration of the present example embodiment will be described below.

As shown in FIG. 3, the length D1 of the connection wire 7 is preferably the minimum distance between the connection portion A and the edge portion 4c of the first main surface 4a of the piezoelectric substrate 4. In such a case, the length D1 of the connection wire 7 is short. Therefore, the contact between the mounting substrate wire 15 and the connection wire 7 can be easily reduced or prevented. Also, the degree of freedom of arrangement of the mounting substrate wires 15 can be increased. For example, the minimum distance D2 between the reference portion B and the mounting substrate wire 15 can be reduced. Thus, the mounting substrate 2 can be miniaturized.

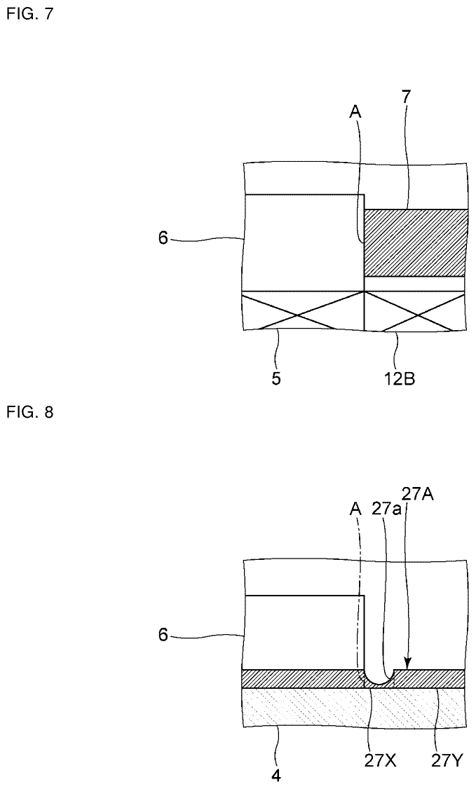

FIG. 7 is a schematic bottom view showing an enlarged area near the connection wire and the functional wire of the first example embodiment.

The width of the connection wire 7 is preferably smaller than the width of the functional wire 6. The width of the connection wire 7 is a dimension of the connection wire 7 along a direction orthogonal or substantially orthogonal to the direction in which the connection wire 7 extends. Similarly, the width of the functional wire 6 is a dimension of the functional wire 6 along a direction orthogonal or substantially orthogonal to the direction in which the functional wire 6 extends. As described above, during dicing, the stress caused by the dicing blade dragging a part of the connection wire 7 propagates to the IDT electrode 5 side. When the width of the connection wire 7 is small, the connection wire 7 is likely to be cut on the connection portion A side. When the connection wire 7 is cut and removed at the connection portion A, the connection wire 7 will not bend toward the mounting substrate wire 15. Or when a portion of the connection wire 7 is cut and removed, the length of the connection wire 7 is reduced. Therefore, the contact of the connection wire 7 with the mounting substrate wire 15 is effectively reduced or prevented. Thus, the degradation of the electrical characteristics of the acoustic wave device 10 can be effectively reduced or prevented.

FIG. 7 shows a case in which the connection wire 7 and the functional wire 6 extend in the same or substantially the same direction, but the present invention is not limited to such a case. The direction in which the connection wire 7 extends and the direction in which the functional wire 6 extends may intersect.

It is preferable that the at least one of the electrode pads 8 shown in FIG. 2, is a floating electrode. There is a risk that the electrode pad 8 may peel off due to the stress caused by the dicing blade dragging a portion of the electrode pad 8. Or the stress may propagate to the surface of the substrate 16 shown in FIG. 5, so that microcracks may occur in the substrate 16. The microcracks may cause the electrode pad 8 to peel off. There is a risk that the electrode pad 8 may contact the mounting substrate wire 15. Even in such a case, since the electrode pad 8 is a floating electrode, the degradation of the electrical characteristics of the acoustic wave device 10 can be reduced or prevented.

Although not shown in the drawings, the functional wire 6 includes a multilayer metal film. It is preferable that a portion of the plurality of metal layers of the functional wire 6 and the connection wire 7 are integrally provided. Thus, the productivity of the acoustic wave device 10 can be improved.

First to third variations of the first example embodiment will be described below. The first to third variations differ from the first example embodiment only in the shape near the connection portion of the connection wire.

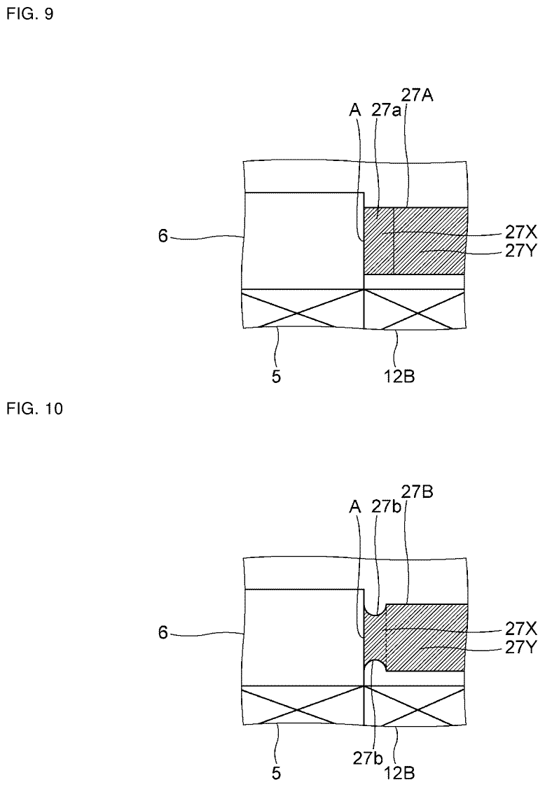

FIG. 8 is a schematic sectional view showing an area near a connection wire and a functional wire of a first variation of the first example embodiment, sectioned along a direction in which the connection wire extends. FIG. 9 is a schematic bottom view showing the area near the connection wire and the functional wire of the first variation of the first example embodiment.

As shown in FIGS. 8 and 9, a connection wire 27A includes a first portion 27X and a second portion 27Y. The first portion 27X is connected to a connection portion A. The second portion 27Y is connected to the first portion 27X. In FIG. 8, a boundary between the first portion 27X and the second portion 27Y is indicated by a dashed line. The same goes for the schematic bottom views showing other variations of the first example embodiment. Hereinafter, a direction in which the connection wire 27A extends is referred to as a connection wire extension direction, and a direction orthogonal or substantially orthogonal to the connection wire extension direction is referred to as a width direction.

As shown in FIG. 8, a recess 27a is provided in the first portion 27X of the connection wire 27A. As shown in FIG. 9, the recess 27a is provided over the entire or substantially the entire connection wire 27A in the width direction. One end portion of the recess 27a in the connection wire extension direction is located at the connection portion A. The other end portion of the recess 27a is located at the boundary between the first portion 27X and the second portion 27Y. In the present variation, the recess 27a is provided over the entire or substantially the entire first portion 27X. In other words, the thickness of the first portion 27X is smaller than the thickness of the second portion 27Y.

When dicing is performed in the process of obtaining the acoustic wave element chip, the connection wire 27A is likely to be cut at the recess 27a. As a result, a portion of the first portion 27X on the side of the second portion 27Y, and the second portion 27Y are likely to be removed. Thus, the contact of the connection wire 27A with the mounting substrate wire 15 can be effectively reduced or prevented.

The shape of the recess 27a, in the section shown in FIG. 8, is semicircular or substantially semicircular. However, the shape of the recess 27a in the above-described section is not limited to semicircular or substantially semicircular. For example, the shape of the recess 27a in the above-described section may be semi-elliptical or substantially semi-elliptical or triangular or substantially triangular. Alternatively, the shape of the recess 27a in the above-described section may be an appropriate shape including a curve, a polygon or the like. In the present description, the triangle and the polygon include those whose apexes are curved.

It is only necessary that the recess 27a is provided in at least a portion of the first portion 27X. In other words, it is only preferable that the thickness of at least a portion of the first portion 27X is smaller than the thickness of the second portion 27Y. More specifically, the recess 27a may be provided in at least a portion of the first portion 27X in a direction intersecting the connection wire extension direction. One end portion of the recess 27a in the connection wire extension direction may be located at a portion away from the connection portion A. Even in such a case, it is easy to shorten the length of the connection wire 27A after dicing. Thus, the contact of the connection wire 27A with the mounting substrate wire 15 can be effectively reduced or prevented.

In the second variation shown in FIG. 10, the width of at least a portion of a first portion 27X of a connection wire 27B is smaller than the width of a second portion 27Y. More specifically, the first portion 27X includes notches 27b at respective edge portions in the width direction. Thus, the width of at least a portion of each of the first portion 27X is reduced. One end portion of the notches 27b in the connection wire extension direction is located at a connection portion A. The other end portion of each of the notches 27b is located at the boundary between the first portion 27X and the second portion 27Y.

When dicing in the process of obtaining the acoustic wave element chip, the connection wire 27B is likely to be cut at the portions where the notches 27b are provided. As a result, a portion of the first portion 27X on the side of the second portion 27Y, and the second portion 27Y are likely to be removed. Thus, the contact of the connection wire 27B with the mounting substrate wire 15 can be effectively reduced or prevented.

The shape of the notch 27b in plan view is semicircular or substantially semicircular. However, the shape of the notch 27b in plan view is not limited to semicircular or substantially semicircular, but may be semi-elliptical or substantially semi-elliptical or triangular or substantially triangular, for example. Alternatively, the shape of the notch 27b in plan view may be an appropriate shape including a curve, a polygon or the like. It is only necessary that the notch 27b be provided on at least one of the edge portions in the width direction.

One end portion of the notch 27b in the direction in which the connection wire 27B extends in may be located at a portion away from the connection portion A. It is only preferable that the width of at least a portion of the first portion 27X is smaller than the width of the second portion 27Y. In such a case, the length of the connection wire 27B can be easily shortened after dicing. Thus, the contact of the connection wire 27B with the mounting substrate wire 15 can be effectively reduced or prevented.

The dimensions or positions of the two notches 27b may be different from each other. In such a case, it is only preferable that the boundary between the first portion 27X and the second portion 27Y passes through, for example, the end portion, among the end portions of the two notches in the connection wire extension direction, farthest from the connection portion A.

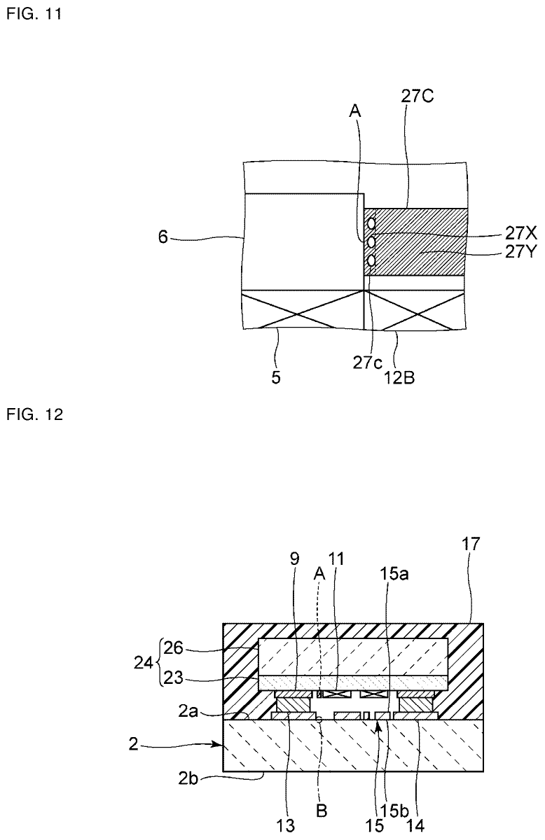

In the third variation shown in FIG. 11, a plurality of through holes 27c are provided in a first portion 27X of a connection wire 27C. More specifically, the plurality of through holes 27c are provided so as to be aligned in the width direction. The end portions of the plurality of through holes 27c on a connection portion A side in the connection wire extension direction are provided away from the connection portion A. The other end portions of the plurality of through holes 27c is located at the boundary between the first portion 27X and the second portion 27Y.

It is preferable that the plurality of through holes 27c are provided so that they are aligned in a direction that intersects the direction in which the connection wire 27C extends. When the plurality of through holes 27c are aligned in a direction other than the width direction, it is preferable that the boundary between the first portion 27X and the second portion 27Y passes through, for example, the end portion, among the end portions of the plurality of through holes 27c in the connection wire extension direction, farthest from the connection portion A.

When dicing in the process of obtaining the acoustic wave element chip, the connection wire 27C is likely to be cut at the portion where the plurality of through holes 27c are provided. As a result, a portion of the first portion 27X on the side of the second portion 27Y, and the second portion 27Y are likely to be removed. Thus, the contact of the connection wire 27C with the mounting substrate wire 15 can be effectively reduced or prevented.

The shape of each of the through holes 27c in plan view is elliptical or substantially elliptical. However, the shape of the through hole 27c in plan view is not limited to elliptical or substantially elliptical, an may be circular, substantially circular, triangular, substantially triangular, polygonal, or substantially polygonal, for example. Alternatively, the shape of the through hole 27c in plan view may be an appropriate shape, including a curve.

As shown in FIG. 2, in the first example embodiment, each of the connection wires 7 has a linear shape. However, the connection wire 7 may have a shape other than a linear shape. For example, the shape of the connection wire 7 may include a curved shape such as an arc shape or a parabolic shape. In such a case, the length D1 of the connection wire 7 is the length of a midline of the connection wire 7. In the present description, the midline of the connection wire 7 is connecting the midpoints of the connection wire 7. The midpoint of any portion of the connection wire 7 is the center or approximate center of the portion in a direction orthogonal or substantially orthogonal to the direction in which the portion extends. The direction in which any portion included in the curved portion of the connection wire 7 extends is the direction in which the tangent line tangent to such a portion extends.

As shown in FIG. 1, in the first example embodiment, the piezoelectric substrate 4 includes only a piezoelectric material. However, the piezoelectric substrate 4 may be a multilayer substrate including a piezoelectric layer. For example, in a fourth variation of the first example embodiment shown in FIG. 12, a piezoelectric substrate 24 includes a support substrate 26 and a piezoelectric layer 23. Thus, the piezoelectric substrate 24 is a substrate having piezoelectricity. The piezoelectric layer 23 is provided on the support substrate 26. A first main surface of the piezoelectric substrate 24 is a main surface of the piezoelectric layer 23 located on the mounting substrate 2 side. In such a case, as in the first example embodiment, the contact between the mounting substrate wire 15 and the connection wire 7 can be reduced or prevented, and the degradation of the electrical characteristics of the acoustic wave device can be reduced or prevented.

For example, a semiconductor such as silicon, a ceramic such as aluminum oxide, or the like can be used as the material of the support substrate 26.

In the present variation, the piezoelectric layer 23 is provided directly on the support substrate 26. However, the piezoelectric layer 23 may be provided indirectly on the support substrate 26 with an intermediate layer interposed therebetween. The intermediate layer may be, for example, a single-layer dielectric film or a multilayer film. For example, a dielectric such as silicon oxide, silicon nitride or silicon oxynitride may be used as the material of the intermediate layer.

The first to four variations can also be applied to configurations other than the first example embodiment of the present invention. At least two of the configurations of the first to fourth variations may be applied simultaneously. For example, the first portion 27X shown in FIG. 9 may include a recess 27a, and a notch 27b shown in FIG. 10.

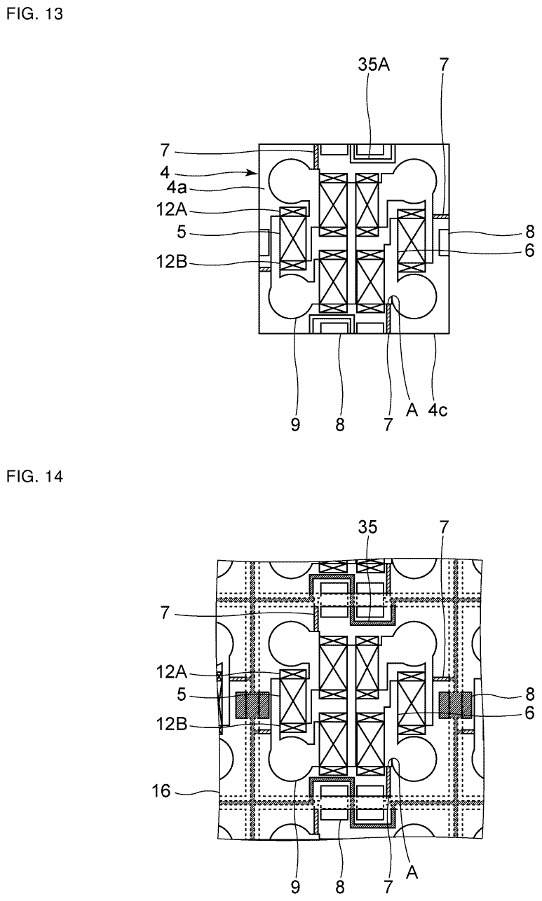

FIG. 13 is a schematic bottom view of an acoustic wave element chip according to a second example embodiment of the present invention. FIG. 14 is a schematic plan view showing a portion of a substrate to be divided when obtaining the acoustic wave element chip of the second example embodiment. In FIG. 14, the dicing line and the portions to be removed by dicing are indicated by dashed lines. Further, in FIG. 14, a wiring electrode 35 and electrode pads 8 connected to the wiring electrode 35 are indicated by hatching.

As shown in FIG. 13, the present example embodiment differs from the first example embodiment in that wiring electrodes 35A are provided on the first main surface 4a of the piezoelectric substrate 4, surrounding the electrode pads 8. Except for the above difference, the acoustic wave device of the present example embodiment has the same or substantially the same configuration as the acoustic wave device 10 of the first example embodiment.

The wiring electrode 35A extends to the edge portion 4c of the first main surface 4a. Thus, specifically, the wiring electrode 35A surrounds the electrode pad 8 in three directions. The wiring electrode 35A surrounds the electrode pad 8 together with the edge portion 4c. On the first main surface 4a of the piezoelectric substrate 4, each of the wiring electrodes 35A surrounds one electrode pad 8. However, the wiring electrode 35A may surround a plurality of electrode pads 8.

In the present example embodiment, the connection wire 7 and the mounting substrate 2 are configured in the same manner as in the first example embodiment. Therefore, the contact between the mounting substrate wire 15 and the connection wire 7 can be reduced or prevented, and the degradation of the electrical characteristics of the acoustic wave device can be reduced or prevented.

In manufacturing the acoustic wave device of the present example embodiment, the substrate 16 shown in FIG. 14 is divided by dicing. The wiring electrode 35A shown in FIG. 13 is formed by removing a portion of the wiring electrode 35 shown in FIG. 14 by dicing.

The wiring electrode 35 is provided so as to be connected to some of the plurality of electrode pads 8 and not connected to others of the plurality of electrode pads 8. More specifically, the wiring electrode 35 includes a portion that is provided so as to bypass the electrode pads 8. The wiring electrode 35 is not connected to the electrode pads 8 that are bypassed by the wiring electrode 35. On the other hand, a portion of the wiring electrode 35 other than the portion that bypasses the electrode pads 8 extends on the dicing line. The portion of the wiring electrode 35 that extends on the dicing line is removed by dicing. The portion of the wiring electrode 35 that bypasses the electrode pads 8 becomes the wiring electrodes 35A after dicing.

The some of the plurality of electrode pads 8 connected to the wiring electrode 35 have the same potential as the wiring electrode 35. The wiring electrode 35 is connected to the ground potential. On the other hand, the others of the plurality of electrode pads 8 not connected to the wiring electrode 35 are connected to a hot potential. In the present description, the hot potential refers to the signal potential. The electrode pattern connected to the ground potential, including the plurality of electrode pads 8, is made common by the wiring electrode 35. Thus, the stability of measurement in the inspection can be improved.

The thickness of the wiring electrode 35 is preferably larger than the thickness of the connection wire 7. For example, the thickness of the wiring electrode 35 may be increased by making the wiring electrode 35 a multilayer structure including a plurality of layers. This also increases the stability of measurement during the inspection.

The pattern of the wiring electrode 35 is not limited to that described above. Another example of the wiring electrode 35 will be described below in a third example embodiment of the present invention. In the third example embodiment, the electrode corresponding to the wiring electrode 35A after dicing is a first wiring electrode.

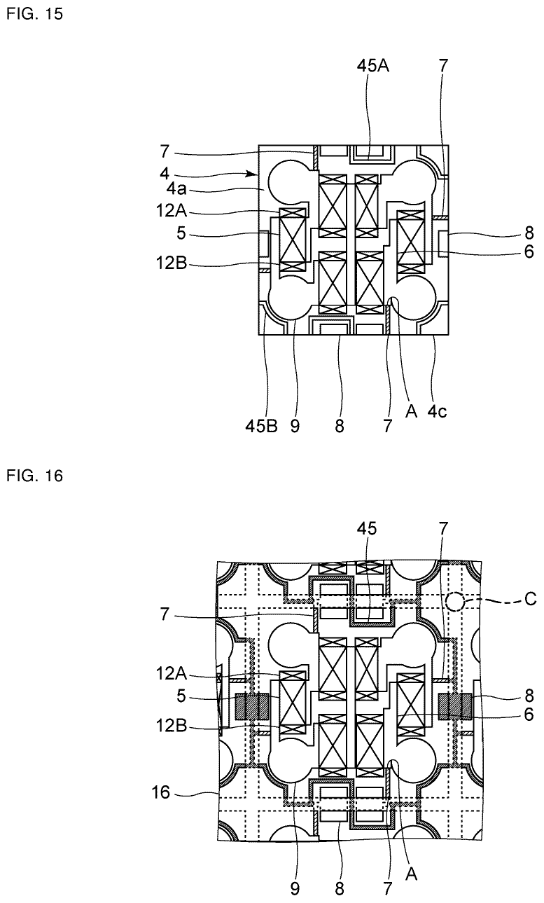

FIG. 15 is a schematic bottom view of an acoustic wave element chip according to the third example embodiment. FIG. 16 is a schematic plan view showing a portion of a substrate to be divided when obtaining the acoustic wave element chip of the third example embodiment. In FIG. 16, the dicing line and the portions to be removed by dicing are indicated by dashed lines. Further, in FIG. 16, a wiring electrode 45 and electrode pads 8 connected to the wiring electrode 45 are indicated by hatching.

As shown in FIG. 15, in the present example embodiment, first wiring electrodes 45A and second wiring electrodes 45B are provided on the first main surface 4a of the piezoelectric substrate 4. The present example embodiment differs from the second example embodiment in that the second wiring electrodes 45B are provided. The second wiring electrode 45B includes a portion provided along the bump pad 9. The second wiring electrode 45B extends to the edge portion 4c of the first main surface 4a. Except for the above difference, the acoustic wave device of the present example embodiment has the same or substantially the same configuration as the acoustic wave device of the second example embodiment.

In the present example embodiment, the connection wire 7 and the mounting substrate 2 are configured in the same or substantially the same manner as in the first example embodiment. Therefore, the contact between the mounting substrate wire 15 and the connection wire 7 can be reduced or prevented, and the degradation of the electrical characteristics of the acoustic wave device can be reduced or prevented.

The first wiring electrode 45A and the second wiring electrode 45B are formed by removing a portion of the wiring electrode 45 shown in FIG. 16 by dicing. More specifically, the wiring electrode 45 includes a portion that bypasses the electrode pad 8, a portion that extends on the dicing line, a portion that extends along the bump pad 9, and a portion that extends toward the dicing line. The portion of the wiring electrode 45 that extends on the dicing line is removed by dicing. The portion of the wiring electrode 45 that bypasses the electrode pad 8 becomes the first wiring electrode 45A after dicing. The portion of the wiring electrode 45 that extends along the bump pad 9 and the portion that extends toward the dicing line become the second wiring electrode 45B after dicing.

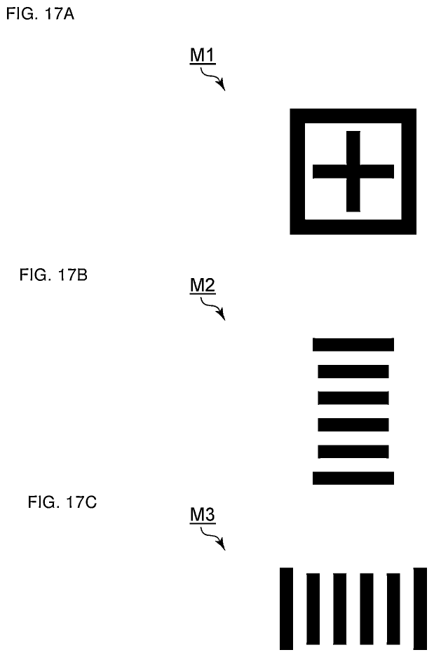

As shown in FIG. 16, the wiring electrode 45 is not provided in the portions where the dicing lines intersect. For example, alignment marks such as marks M1 to M3 shown in FIGS. 17A to 17C, which are used during the manufacturing process using a photolithography technique, can be arranged at intersection portions C, which are the portions where the dicing lines intersect.

In the present example embodiment, the electrode pattern connected to the ground potential is also made common by the wiring electrode 45. Thus, the stability of measurement in the inspection can be improved.

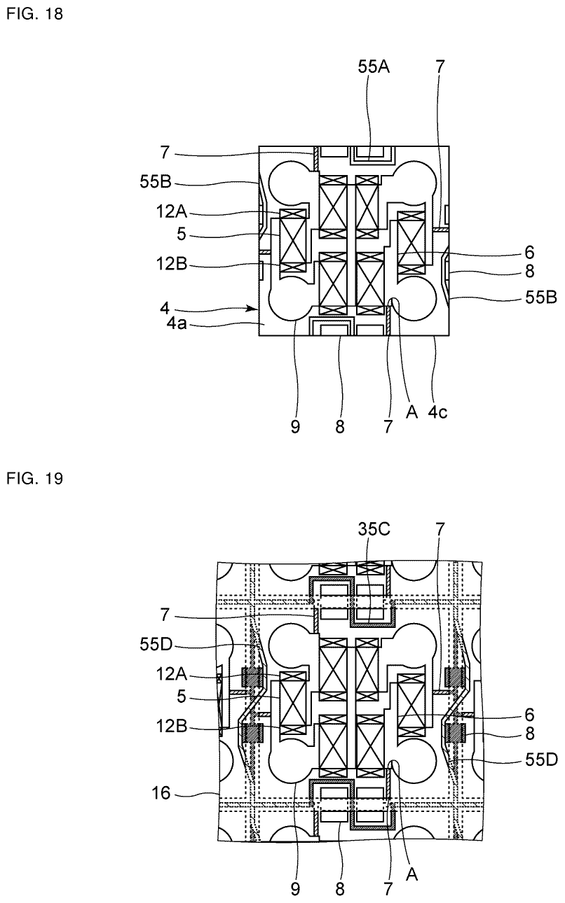

FIG. 18 is a schematic bottom view of an acoustic wave element chip according to a fourth example embodiment of the present invention. FIG. 19 is a schematic plan view showing a portion of a substrate to be divided when obtaining the acoustic wave element chip of the fourth example embodiment. In FIG. 19, the dicing line and the portions to be removed by dicing are indicated by dashed lines. Further, in FIG. 19, a first-layer wiring electrode and a second-layer wiring electrode, and electrode pads connected to first-layer wiring electrode and second-layer wiring electrode, all of these components will be described later, are indicated by hatching. The same goes for schematic plan views that follow FIG. 19 and show a portion of the substrate.

As shown in FIG. 18, the present example embodiment differs from the second example embodiment in that second wiring electrodes 55B are provided. The present example embodiment also differs from the second example embodiment in the number of electrode pads 8 and the position of the connection wire 7. Except for the above differences, the acoustic wave device of the present example embodiment has the same or substantially the same configuration as the acoustic wave device of the second example embodiment. In the present example embodiment, the length of the connection wire 7, and the functional wire 6 to which the connection wire 7 is connected are the same or substantially the same as those in the second example embodiment.

First wiring electrode 55A is provided in the same or substantially the same manner as the wiring electrode 35A in the second example embodiment shown in FIG. 13. The first wiring electrode 55A is provided so as to surround the electrode pad 8.

A portion of the second wiring electrode 55B is connected to the electrode pad 8. Both end portions of the second wiring electrode 55B extend to the edge portion 4c of the first main surface 4a of the piezoelectric substrate 4. The electrode pad 8 connected to the second wiring electrode 55B is an electrode pad 8 different from the electrode pad 8 surrounded by the first wiring electrode 55A. In the present example embodiment, the material of the second wiring electrode 55B is different from the material of the first wiring electrode 55A and the material of the electrode pad 8. The material of the second wiring electrode 55B may also be the same as the material of the first wiring electrode 55A and the material of the electrode pad 8.

In the present example embodiment, the mounting substrate 2 is configured in the same or substantially the same manner as in the second example embodiment, for example, and the length D1 of the connection wire 7 satisfies D1<(D2²+H1²)^{0.5}. Therefore, the contact between the mounting substrate wire 15 and the connection wire 7 can be reduced or prevented, and the degradation of the electrical characteristics of the acoustic wave device can be reduced or prevented.

The first wiring electrode 55A and the second wiring electrode 55B are formed by removing a portion of a first-layer wiring electrode 35C and a second-layer wiring electrode 55D shown in FIG. 19 by dicing. More specifically, the portion of the first-layer wiring electrode 35C not removed by dicing becomes the first wiring electrode 55A shown in FIG. 18. On the other hand, the portion of the second-layer wiring electrode 55D not removed by dicing becomes the second wiring electrode 55B.

The first-layer wiring electrode 35C shown in FIG. 19 includes a portion that is provided so as to bypass the electrode pad 8. A portion of the aforesaid portion of the first-layer wiring electrode 35C becomes the first wiring electrode 55A shown in FIG. 18. A portion of the first-layer wiring electrode 35C other than the aforesaid portion extends on the dicing line. The electrode pad 8 that is bypassed by the first-layer wiring electrode 35C is connected to the signal potential. On the other hand, the first-layer wiring electrode 35C is connected to the electrode pad 8 connected to the ground potential. The portion where the electrode pad 8 and the first-layer wiring electrode 35C are connected is located on the dicing line.

The second-layer wiring electrode 55D includes a laminated portion and a bypass portion. More specifically, the laminated portion is a portion, in the second-layer wiring electrode 55D, that is laminated on the first-layer wiring electrode 35C. The laminated portion is located on the dicing line. The second-layer wiring electrode 55D is not laminated on the portion, in the first-layer wiring electrode 35C, that bypasses the electrode pad 8. The second-layer wiring electrode 55D is not connected to the electrode pad 8 connected to the signal potential.

The bypass portion is a portion, in the second-layer wiring electrode 55D, that is provided so as to bypass a portion to which the electrode pad 8 and the first-layer wiring electrode 35C are connected. The bypass portion is provided directly on the substrate 16. The bypass portion is connected to the electrode pad 8 connected to the ground potential. In other words, such an electrode pad 8 is connected to the first-layer wiring electrode 35C on the dicing line and connected to the second-layer wiring electrode 55D outside the dicing line. A portion of the bypass portion of the second-layer wiring electrode 55D becomes the second wiring electrode 55B shown in FIG. 18.

The first-layer wiring electrode 35C corresponds to the wiring electrode 35 in the second example embodiment. Even in the present example embodiment, the electrode pattern connected to the ground potential is made common by the first-layer wiring electrode 35C. Further, the second-layer wiring electrode 55D is laminated on a portion of the first-layer wiring electrode 35C. Thus, the electrical resistance of the electrode pattern connected to the ground potential can be reduced. Therefore, the stability of measurement in the inspection can be effectively improved.

Additionally, as described above, the second-layer wiring electrode 55D includes the bypass portion. Thus, the portion where the electrode pattern is thicker on the dicing line can be reduced. Thus, dicing can be facilitated, and productivity can be improved.

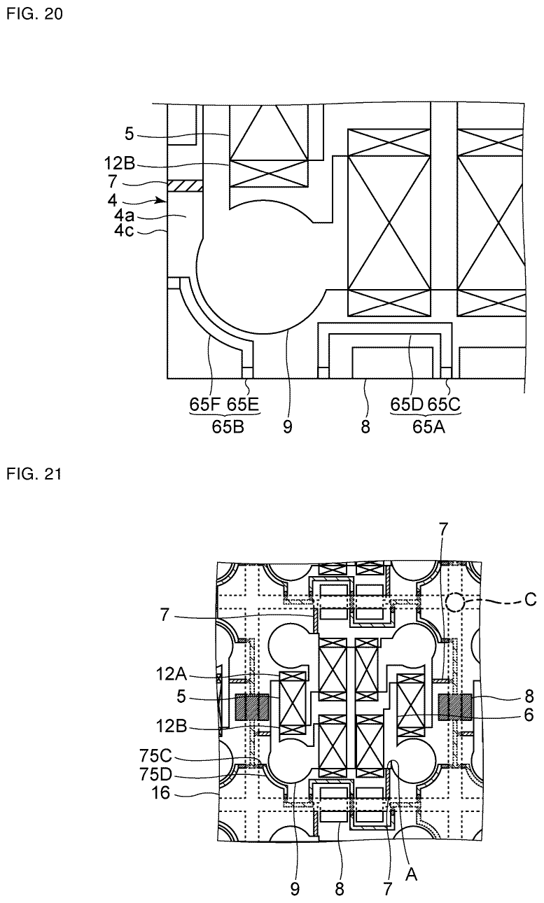

FIG. 20 is a schematic bottom view showing an enlarged portion of an acoustic wave element chip according to a fifth example embodiment of the present invention. FIG. 21 is a schematic plan view showing a portion of a substrate to be divided when obtaining the acoustic wave element chip of the fifth example embodiment.

As shown in FIG. 20, the present example embodiment differs from the third example embodiment in that first wiring electrodes 65A and second wiring electrodes 65B are multilayer bodies. Except for the above difference, the acoustic wave device of the present example embodiment has the same or substantially the same configuration as the acoustic wave device of the third example embodiment.

In the present example embodiment, the connection wire 7 and the mounting substrate 2 are configured in the same or substantially the same manner as in the third example embodiment. Therefore, the contact between the mounting substrate wire 15 and the connection wire 7 can be reduced or prevented, and the degradation of the electrical characteristics of the acoustic wave device can be reduced or prevented.

The first wiring electrode 65A is provided so as to surround the electrode pad 8. The first wiring electrode 65A includes a first-layer wiring electrode 65C and a second-layer wiring electrode 65D. The second-layer wiring electrode 65D is laminated on the first-layer wiring electrode 65C.

The first-layer wiring electrode 65C is configured in the same or substantially the same manner as the first wiring electrode 45A in the third example embodiment shown in FIG. 15. Therefore, both end portions of the first-layer wiring electrode 65C extend to the edge portion 4c of the first main surface 4a of the piezoelectric substrate 4.

On the other hand, the second-layer wiring electrode 65D is laminated on a portion of the first-layer wiring electrode 65C. More specifically, the second-layer wiring electrode 65D is laminated on a portion of the first-layer wiring electrode 65C other than the vicinity of the end portions. Therefore, the vicinity of the end portions of the first-layer wiring electrode 65C is exposed from the second-layer wiring electrode 65D. Neither of the two end portions of the second-layer wiring electrode 65D extends to the edge portion 4c of the first main surface 4a of the piezoelectric substrate 4.

The second wiring electrode 65B includes a portion provided along the bump pad 9. The second wiring electrode 65B includes a first-layer wiring electrode 65E and a second-layer wiring electrode 65F. The second-layer wiring electrode 65F is laminated on the first-layer wiring electrode 65E.

The first-layer wiring electrode 65E is configured in the same or substantially the same manner as the second wiring electrode 45B in the third example embodiment shown in FIG. 15. Thus, both end portions of the first-layer wiring electrode 65E extend to the edge portion 4c of the first main surface 4a of the piezoelectric substrate 4.

On the other hand, the second-layer wiring electrode 65F is laminated on a portion of the first-layer wiring electrode 65E other than the vicinity of the end portions. Therefore, neither of the two end portions of the second-layer wiring electrode 65F extends to the edge portion 4c of the first main surface 4a of the piezoelectric substrate 4.

The first wiring electrode 65A and the second wiring electrode 65B are formed by removing a portion of a first-layer wiring electrode 75C and a second-layer wiring electrode 75D shown in FIG. 21 by dicing. The second-layer wiring electrode 75D is laminated on the first-layer wiring electrode 75C. The portions of the first-layer wiring electrode 75C not removed by dicing become the first-layer wiring electrode 65C and the first-layer wiring electrode 65E shown in FIG. 20. On the other hand, the portions of the second-layer wiring electrode 75D not removed by dicing become the second-layer wiring electrode 65D and the second-layer wiring electrode 65F.

The first-layer wiring electrode 75C shown in FIG. 21 corresponds to the wiring electrode 45 in the third example embodiment shown in FIG. 16. Specifically, the first-layer wiring electrode 75C includes a portion that bypasses the electrode pad 8, a portion that extends on the dicing line, a portion that extends along the bump pad 9, and a portion that extends toward the dicing line.

The second-layer wiring electrode 75D is laminated on a portion of the first-layer wiring electrode 75C other than the vicinity of the edge portion of the dicing line. Thus, after dicing, the second-layer wiring electrode 65D does not extend to the edge portion 4c of the first main surface 4a of the piezoelectric substrate 4, as shown in FIG. 20.

Here, when the wiring electrode is a multilayer body, the stress applied to the wiring electrode tends to be large during dicing. More specifically, the stress applied between the portion of the wiring electrode that is removed by dicing and the portion that is not removed tends to be large. Due to such a stress, microcracks or cracks larger than microcracks may occur in the piezoelectric substrate.

In contrast, in the present example embodiment, as shown in FIG. 21, the second-layer wiring electrode 75D is not provided in the vicinity of the edge portion of the dicing line. Therefore, the vicinity of the edge portion of the dicing line, the wiring electrode is not a multilayer body. Thus, the stress applied to the wiring electrode during dicing can be reduced. Therefore, generation of cracks in the piezoelectric substrate 4 shown in FIG. 20 can be reduced or prevented.

As shown in FIG. 21, the electrode pattern connected to the ground potential is made common by the first-layer wiring electrode 75C. Further, the second-layer wiring electrode 75D is laminated on a portion of the first-layer wiring electrode 75C. Thus, the electrical resistance of the electrode pattern connected to the ground potential can be reduced. Thus, the stability of measurement in the inspection can be effectively improved.

The first to fifth example embodiments describe examples in which the functional electrode is an IDT electrode, and the acoustic wave resonator is a surface acoustic wave resonator, for example. However, the acoustic wave resonator in the present invention may be, for example, a BAW (bulk acoustic wave) element. In such a case, the functional electrodes may include a pair of plate electrodes. The pair of plate electrodes may face each other with the piezoelectric substrate interposed therebetween. When the piezoelectric substrate is a multilayer substrate, the pair of plate electrodes may face each other with the piezoelectric layer interposed therebetween.

Even in the case where the acoustic wave resonator is a BAW device, for example, it is only necessary that D1<(D2²+H1²)^{0.5} be satisfied, as in the first through fifth example embodiments.

Therefore, the contact between the mounting substrate wire and the connection wire can be reduced or prevented, and the degradation of the electrical characteristics of the acoustic wave device can be reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a first main surface and a second main surface facing each other;
a functional electrode on the first main surface of the piezoelectric substrate;
a functional wire on the first main surface of the piezoelectric substrate and connected to the functional electrode; and
a connection wire on the first main surface of the piezoelectric substrate, connected to the functional wire, and extending to an edge portion of the first main surface; wherein
an acoustic wave element chip is defined by the piezoelectric substrate, the functional electrode, the functional wire, and the connection wire;
the acoustic wave device further includes:
a mounting substrate on which the acoustic wave element chip is mounted and including a third main surface facing the first main surface of the piezoelectric substrate; and
a mounting substrate wire on the third main surface of the mounting substrate and including a first surface on a side of the acoustic wave element chip and a second surface facing the first surface; and
D1<(D2²+H1²)^{0.5} is satisfied, when a portion where the functional wire and the connection wire are connected is a connection portion, a portion of the mounting substrate overlapping the connection portion in plan view is a reference portion, a length of the connection wire is D1, a minimum distance between the reference portion and the mounting substrate wire is D2, and a distance between the first main surface of the piezoelectric substrate and the first surface of the mounting substrate wire is H1.

2. The acoustic wave device according to claim 1, wherein a thickness of the connection wire is smaller than a thickness of the functional wire.

3. The acoustic wave device according to claim 1, wherein a width of the connection wire is smaller than a width of the functional wire.

4. The acoustic wave device according to claim 1, wherein
the connection wire includes a first portion connected to the connection portion and a second portion connected to the first portion; and
a thickness of at least a portion of the first portion is smaller than a thickness of the second portion.

5. The acoustic wave device according to claim 1, wherein
the connection wire includes a first portion connected to the connection portion and a second portion connected to the first portion; and
a width of at least a portion of the first portion is smaller than a width of the second portion.

6. The acoustic wave device according to claim 1, wherein
the connection wire includes a first portion connected to the connection portion; and
the first portion includes a plurality of through holes aligned in a direction intersecting a direction in which the connection wire extends.

7. The acoustic wave device according to claim 1, further comprising at least one electrode pad provided on the first main surface of the piezoelectric substrate and extending to the edge portion.

8. The acoustic wave device according to claim 7, wherein the at least one electrode pad is not connected to a signal potential or a ground potential.

9. The acoustic wave device according to claim 8, further comprising a wiring electrode provided on the first main surface of the piezoelectric substrate so as to surround the electrode pad and reach the edge portion.

10. The acoustic wave device according to claim 1, wherein the functional electrode is an interdigital transducer electrode.

11. The acoustic wave device according to claim 1, wherein the piezoelectric substrate includes a support substrate and a piezoelectric layer on the support substrate.

12. The acoustic wave device according to claim 1, wherein the piezoelectric substrate includes only a piezoelectric material.

13. The acoustic wave device according to claim 12, wherein the piezoelectric material includes lithium tantalate, lithium niobate, zinc oxide, aluminum nitride, quartz, or lead zirconate titanate.

14. The acoustic wave device according to claim 1, wherein an electrode pad and a bump pad are provided on the first main surface.

15. The acoustic wave device according to claim 1, wherein a length of the connection wire is a minimum distance between the connection portion and the edge portion.

16. The acoustic wave device according to claim 1, wherein the connection wire and the functional wire extend in a same or substantially a same direction.

17. The acoustic wave device according to claim 1, wherein the functional wire includes a multilayer metal film.

18. The acoustic wave device according to claim 4, wherein the first portion of the connection wire includes a recess.
